(19) United States
(12) Patent Application Publication
(10) Pub. No.: US 2007/0131847 A1
(43) Pub. Date: Jun. 14, 2007

(54) Optical detector

(76) Inventors: Jianguo Yao, Oxon (GB); David Spokes, Bucklebury (GB); Alistair Frier, Northampton (GB); Steven Borley, Towcester (GB)

Correspondence Address: SUGHRUE MION, PLLC, 2100 PENNSYLVANIA AVENUE, N.W., SUITE 800, WASHINGTON, DC, 20037, US

(21) Appl. No.: 10/581,904

(22) PCT Filed: Oct. 21, 2005
(86) PCT No.: PCT/GB05/04072

§ 371 Date: Jun. 7, 2006

Related U.S. Application Data
(60) Provisional application No. 60/625,589, filed on Nov. 8, 2004.

(30) Foreign Application Priority Data
Oct. 25, 2004 (GB) 0423669.1

(51) Int. Cl. H01J 40/14; G01J 1/44; H03F 3/08

(52) U.S. Cl. 250/214 R

(57) ABSTRACT

An optical detector including an avalanche photodiode (APD) and protection circuitry for protecting the APD from excessive power dissipation therewithin, wherein the protection circuitry includes a switching element connected in parallel with the APD, which switching element is switched from a high resistance state to a low resistance state if the level of current through the APD exceeds a predetermined level, and wherein switching back of the switching element to the high resistance state is dependent on a reset signal from a controller. An optical detector including an avalanche photodiode (APD), and protection circuitry for protecting the APD from excessive power dissipation therewithin by switching the APD to a relatively low voltage power supply if the level of current through the APD exceeds a predetermined level, and wherein switching back of the APD to a higher voltage power supply is dependent on a reset signal from a controller.

The present invention relates to optical detectors incorporating avalanche photodiodes (APDs).

APD detectors used in fibre optic receivers can be very vulnerable to high input optical power due to their internal optical gain and the overload capability of the electronics (TIA) downstream thereof. Failure of the APD is a power effect, caused by Joule heating within the detector.

It is an aim of the present invention to provide a new APD optical detector with which the APD is effectively protected against the risk of damage and failure from optical overload.

According to a first aspect of the present invention, there is provided an optical detector including an avalanche photodiode (APD) and protection circuitry for protecting the APD from excessive power dissipation therewithin, wherein the protection circuitry includes a switching element connected in parallel with the APD, which switching element is switched from a high resistance state to a low resistance state if the level of current through the APD exceeds a predetermined level, and wherein switching back of the switching element to the high resistance state is dependent on a reset signal from a controller.

One embodiment includes the following additional features. The protection circuitry also includes a comparator whose output controls said switching element, wherein said comparator receives at its non-inverting input a voltage signal dependent on sum of the levels of current through the APD and the switching element and at its inverting input a reference voltage signal, and wherein the protection circuitry is configured such that switching of said switching element into the low resistance state has the effect of reducing the bias across the APD whilst not reducing the sum of the levels of current through the APD and the switching element, such that in the absence of said reset signal the switching element is latched in the low resistance state. The protection circuitry includes a resistor in series with both the APD and the switching element, the resistance value of the resistor being selected in relation to that of the APD and switching element such that switching the switching element into the low resistance state has the effect of reducing the bias voltage across the APD. The reset signal reduces the bias voltage across the APD and the switching element, whereby the sum of the levels of current through the APD and the switching element drops and said switching element is switched back into the high resistance state. After reducing said bias voltage the controller initiates ramping of said bias voltage back to a normal operation level. The output of the comparator is also connected to an input of the controller.

According to another aspect of the present invention, there is provided an optical detector including an avalanche photodiode (APD), and protection circuitry for protecting the APD from excessive power dissipation therewithin, wherein in the event that the level of current through the APD exceeds a predetermined level as a result of an optical overload, the protection circuitry switches the APD bias voltage to a relatively low bias voltage at which said optical overload can nonetheless still be detected, and wherein switching back of the APD bias voltage to a higher voltage state is dependent on a reset signal from a controller.

In one embodiment, the optical detector further includes a current monitor connected in series with the APD, and wherein the current monitor provides an output signal indicative of the APD current both under normal operation conditions and said overload condition.

According to another aspect of the present invention, there is provided an optical detector including an avalanche photodiode (APD)₅ and protection circuitry for protecting the APD from excessive power dissipation therewithin by switching the APD to a relatively low voltage power supply if the level of current through the APD exceeds a predetermined level, and wherein switching back of the APD to a higher voltage power supply is dependent on a reset signal from a controller.

One embodiment includes the following additional features. The protection circuitry includes a comparator which receives at its inverting input a voltage signal dependent on the level of current through the APD and at its non-inverting input a reference voltage signal, and wherein the protection circuitry is configured such that said reference voltage signal is automatically reduced when the APD is switched to the relatively low voltage power supply such that in the absence of said reset signal the APD is latched in a low bias voltage state even if the level of current through the APD falls back below said predetermined level. The protection circuitry includes a diode connected in series across the output and non-inverting input of the comparator. The diode is connected in series with a switch element across the output and non-inverting input of the comparator, said switch element being switchable between high and low resistance states, and wherein the controller resets the protection circuitry by activating said switch element so as to switch it first to said high-resistance state whereby the APD is switched back to a higher voltage power supply, and then switching it back to said low-resistance state. The low voltage power supply is one at which the controller can still determine the level of current through the APD. The controller receives via a current monitor, amplifier and analogue-digital converter a digital input representative of the current through the APD, and upon determination that the current has dropped below a predetermined level indicating removal of optical overload sends said reset signal to switch the APD back to a higher voltage power supply.

Another embodiment includes the following features. The controller also controls a variable optical attenuator (VOA) in the optical path to the APD. Upon recognition of a switch of the APD to the low voltage power supply the controller sets the VOA to maximum attenuation and switches the APD to a higher voltage power supply.

According to another aspect of the present invention, there is provided the use of the optical detector described above for measuring the power of an optical signal whilst protecting the APD from optical overload.

Embodiments of the invention are hereunder described in detail, by way of example only, with reference to the accompanying drawings, in which:

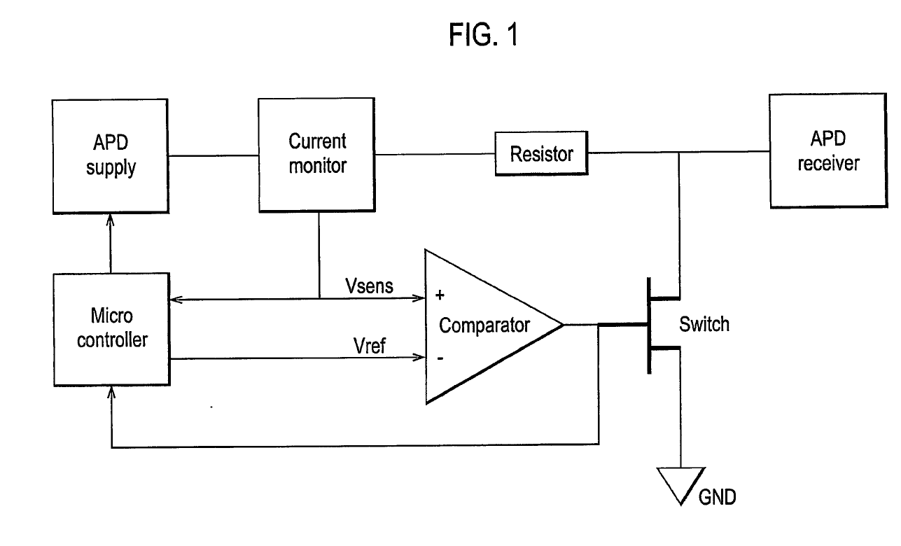

FIG. 1 is a schematic view of an optical detector according to a first embodiment of the invention;

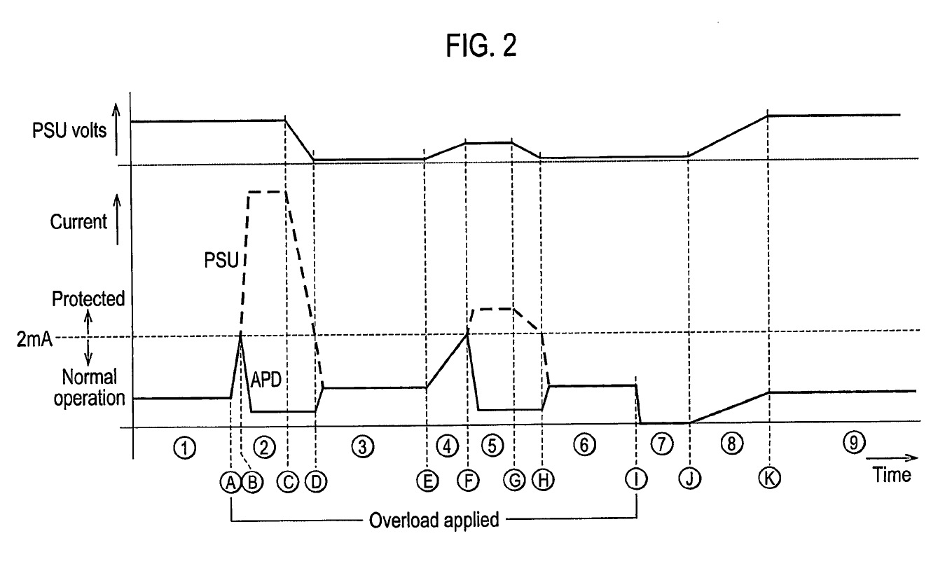

FIG. 2 explains the operation of the detector of FIG. 1 and is a plot against time of current through the APD, current through the power supply unit and the voltage of the power supply;

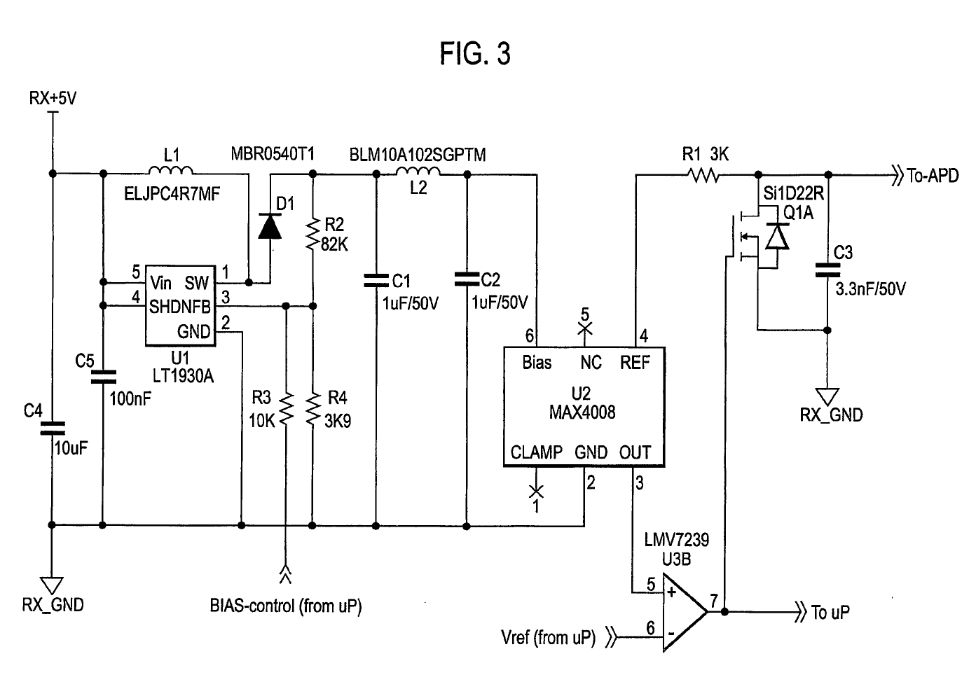

FIG. 3 is a detailed circuit diagram of an example of analogue protection circuitry for the first embodiment;

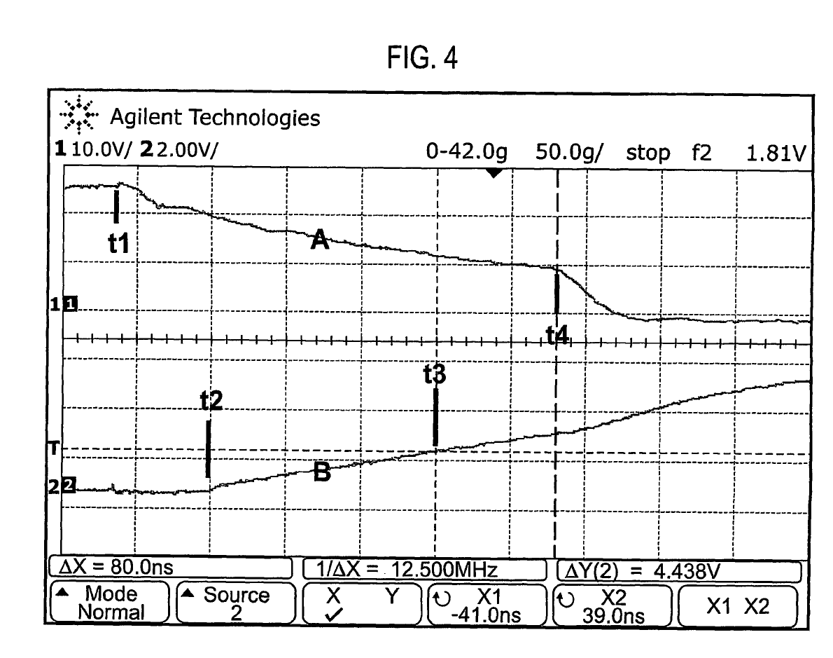

FIG. 4 shows the response of the protection circuitry of FIG. 3 to an overload at the APD, and is a plot against time of APD bias voltage and APD bias current;

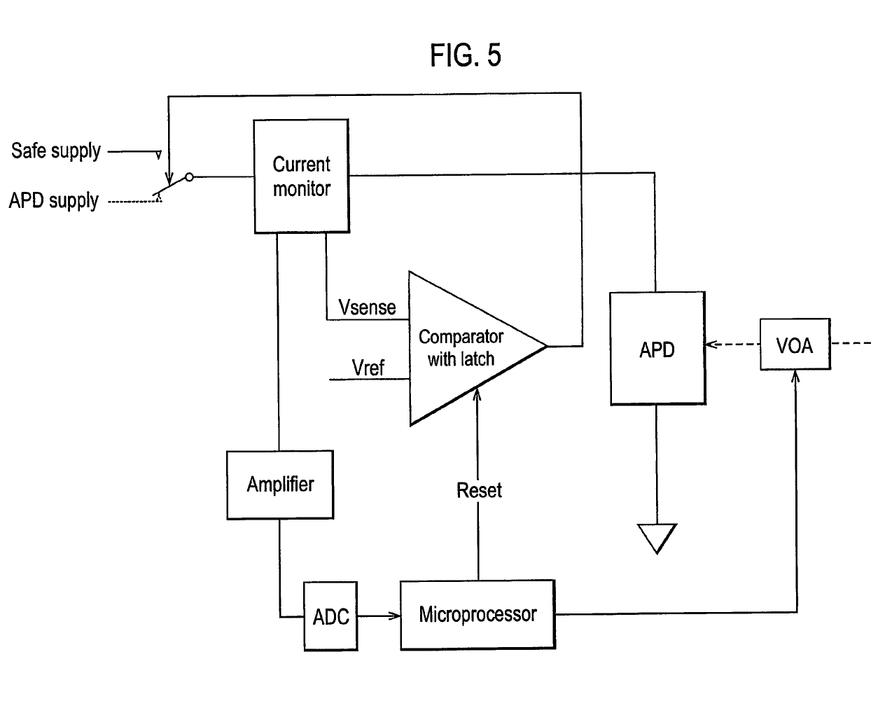

FIG. 5 is a schematic view of an optical detector according to a second embodiment of the present invention;

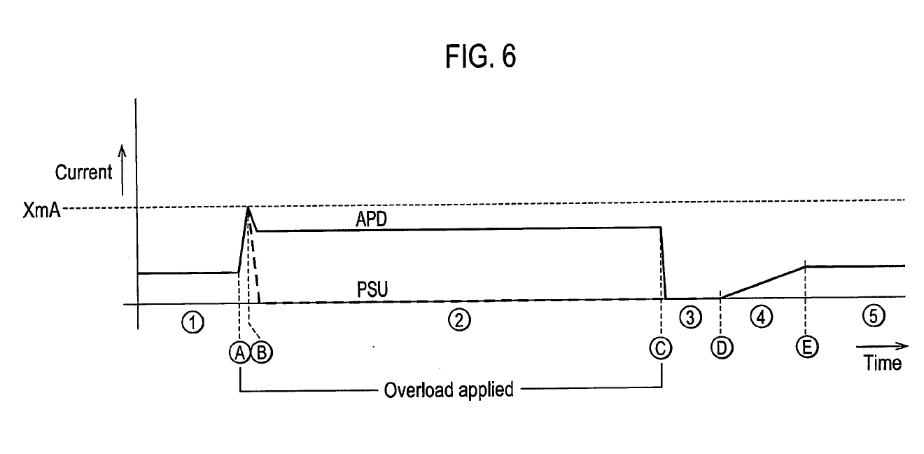

FIG. 6 explains the operation of the detector of FIG. 5 and is a plot against time of the current through the APD and the power supply voltage;

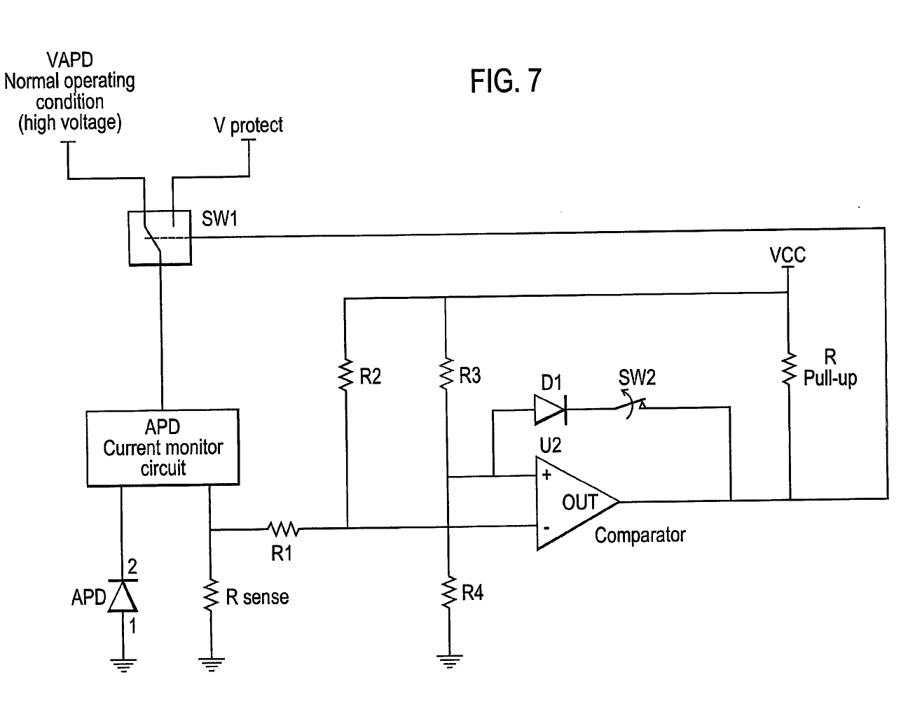

FIG. 7 is a simplified circuit diagram of an example of analogue protection circuitry for the second embodiment;

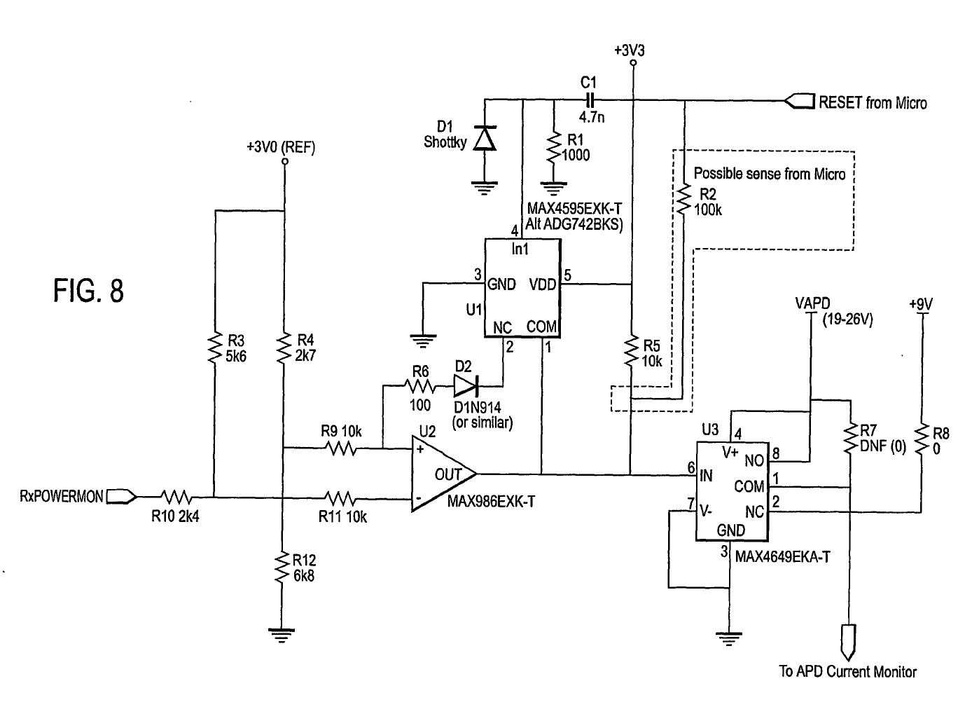

FIG. 8 is a detailed circuit diagram of an example of analogue protection circuitry for the second embodiment;

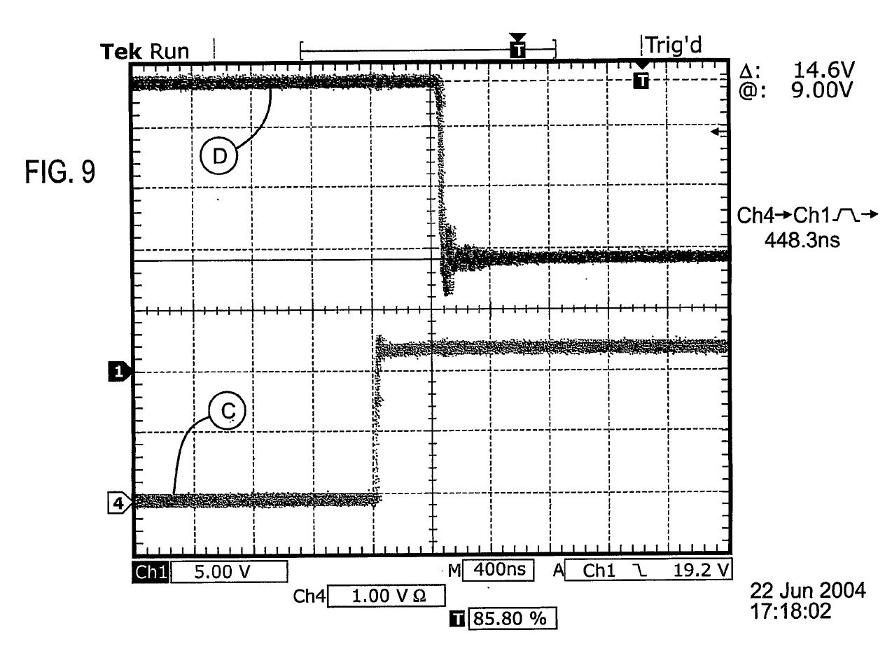

FIG. 9 shows the response of the detector of FIG. 8 and to a sudden arrival of current, and includes a plot of APD supply voltage against time;

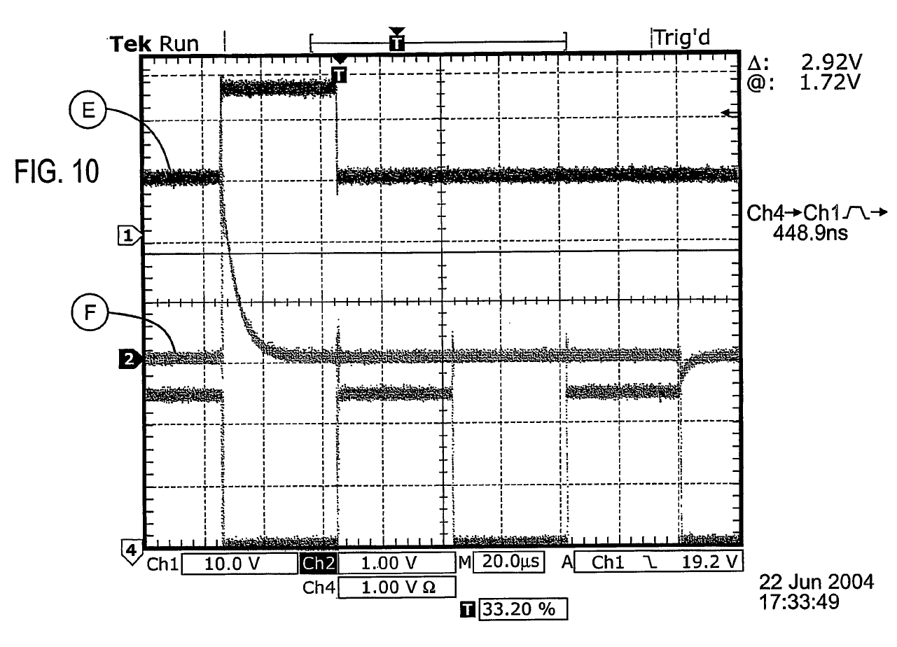

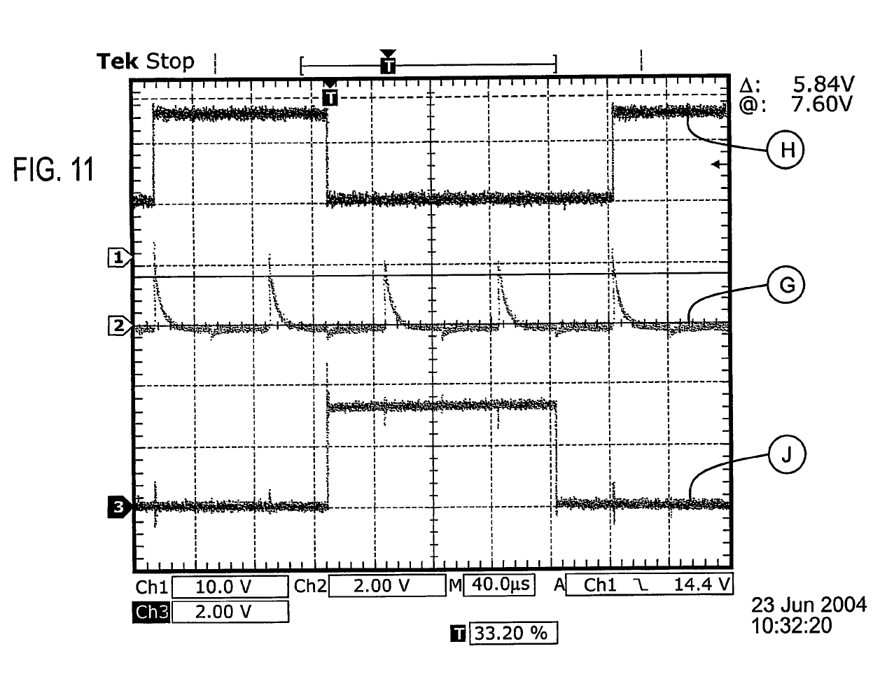

FIGS. 10 and 11 show the response of the protection circuitry of the detector of FIG. 8 to reset signals from the microprocessor, and includes a plot against time of the APD supply voltage and the reset signal voltage from the microprocessor.

With reference to FIG. 1, an optical detector according to a first embodiment of the present invention includes analogue protection circuitry that is configured such that (1) current flowing in the APD (bias-current) is monitored to generate a proportional voltage Vsense at the non-inverting input of the comparator; (2) when the bias-current exceeds a preset limit, Vsense becomes greater than Vref at the inverting input of the comparator; (3) the comparator output then toggles and closes a switch across the APD, whereby a non current-limited path for photocurrent is provided; (4) the closed switch causes increased current to flow through the current monitor, which maintains the comparator output and thereby creates a latch effect; (5) the latch can only be reset by reducing the voltage of the bias supply under the control of a reset signal from a digital microprocessor so that Vsense falls below Vref; at which reduced voltage it is safe to re-connect the supply to the APD.

An explanation of the operation of the detector of the first embodiment is provided by FIG. 2 and the following description of the events marked in FIG. 2.

| Key | Description |
|---|---|
| 1 | APD operating normally, with tolerable input optical power |
| A | Optical overload applied |
| | APD current rises rapidly |
| B | Current reaches 2 mA threshold |
| | Protect circuit trips |
| | APD is shorted - APD current drops due to disconnected bias |
| | PSU current rises due to increased load. This latches protect |
| | circuit in tripped state |
| 2 | PSU maintains previous bias output |
| C | CPU sets the PSU to low voltage - PSU volts and current fall |
| D | Current drops below 2 mA and protect circuit unlatches |
| | PSU current now APD current, but bias volts are very low |
| 3 | CPU waits for a nominal time (e.g. 100 ms) |
| E | CPU starts to restore normal bias |
| 4 | APD bias volts increase, current rises |
| E | Because overload is still applied, current reaches 2 mA |
| | threshold as at B |
| E-H | Cycle A-D repeats |
| 6-7 | CPU waits for a nominal time (e.g. 100 ms) |
| I | Overload condition removed |
| J | CPU attempts to restore normal bias |
| 8 | APD bias volts increase, current rises |
| K | Voltage reaches normal bias level, normal bias current |
| 9 | APD operating normally as at 1 |

The use of a combination of hardware and software controls in this first embodiment provides good overload protection for the APD based optical receiver. The hardware side includes a fast switch which preferable has a response time of less than 1 us. The software side monitors the input optical power and adjusts the APD bias accordingly. The use of a switch to connect APD anode to ground also simplifies the protection circuitry and reduces the number of components to a minimum. This can be very important for APD receivers used in TxRx module applications (such as SFP and XFP) where the board space and power consumption is very critical.

Features of this first embodiment include: (i) switching the APD anode to ground when the input power exceeds a pre-set threshold; (ii) Self-latching to keep the protection switch in the on-state while the software runs the protection routine; and (iii) intelligent multi-mode operation of the APD charge pump.

In FIG. 3, which shows a detailed example of analogue protection circuitry for the first embodiment:

U1 is a 5 to 38V DAC controlled switch-mode PSU. Output volts developed across C2.

U2 is a current sensor with a transfer ratio =IVAmA

U3B is a high-speed comparator. Threshold voltage is set by R5/R6=2 volts, which corresponds to APD bias-current of 2 mA.

In normal operation, the APD bias current is <<2 mA and the APD is biased to the required voltage. If bias current exceeds 2 mA, the comparator output-goes high and rapidly turns on FET Q1A. This shorts out the APD. Any charge generated in the APD flows through Q1A to ground. Power supply current also flows through Q1A via R1. Assuming the APD was biased at >6V, current >2 mA still flows through the current sensor and the comparator output remains high, holding Q1A on, hence the circuit is latched in the protect state. The output of the comparator is also connected to an input port of the microprocessor, so that it recognises the latched trip state.

To reset the latched condition, the microprocessor turns down the bias voltage (via DAC) so that current through the current sensor drops below 2 mA and Q1A turns off. The APD will now be biased at low voltage (<6V). The microprocessor can now restart the bias control loop, which ramps the bias voltage. If the overload is still present, APD current will increase. If it exceeds 2 mA, the cycle will repeat. The processor retry period can be selected as appropriate, for example in the order of 10˜100 ms.

Response time of the latch is preferably <<1 us. FIG. 4 shows the quick response of the protection circuitry shown in FIG. 6 to an overload at the APD. Trace A is the APD bias voltage @1OV/div, and Trace B is the APD bias current @2 mA/div at the current-sensor (MAX4008) output.

The traces show the following:
1. 1OO ohm load applied at APD at t1 . APD bias voltage (A) falls due to supply compliance.
2. Bias current at MAX4008 output starts to rise at t2.
3. Comparator (U3B) threshold is reached at t3.
4. FET (Q1A) turns on at t4.
5. APD bias voltage falls rapidly to 0 volts. The voltage profile is smoothed by the 3.3 nF capacitor across APD.

As shown by the traces, the time for the MAX4008 to respond is t2−t1=70 ns, and the comparator/FET switching time is t4−13=80 ns, making a total circuit delay of only 150 ns.

As shown in FIG. 5, an optical detector according to a second embodiment of the present invention includes analogue protection circuitry that is configured such that (1) Current flowing in the APD (bias-current) is monitored to generate a proportional voltage Vsense; (2) if bias-current exceeds a preset limit, Vsense becomes greater than Vref, whereby the comparator output toggles into a latched ‘tripped’ state; and (3) the APD bias voltage is thus switched to a ‘safe’ voltage. Because the switch is at the input to the current monitor, bias current can still be monitored in the tripped state. The latch is reset by the microprocessor only when the bias current is seen to be at a normal level.

An example of the operation of the detector of this second embodiment is provided by FIG. 6 and the following description of the events marked in FIG. 6.

| Key | Description |
|---|---|
| 1 | APD operating normally, with tolerable input optical power |
| A | Optical overload applied |
| | APD current rises rapidly |
| B | Current reaches preset threshold |
| | Protect circuit trips and self-latches |
| | APD bias switches over to a ‘safe’ low-voltage |
| | supply - APD current drops accordingly |
| 2 | Bias current remains at low level while overload persists |
| | PSU maintains previous bias output, but is disconnected from APD |
| C | Overload condition removed |
| 3 | Bias current drops to very low level due to low bias volts |
| D | CPU detects low current state and resets protect circuit |
| | APD bias-control loop restarts |
| 4 | APD bias volts increase, current rises |
| E | Voltage reaches normal bias level, normal bias current |
| 5 | APD operating normally as at 1 |

The effect of the analogue protection circuitry is to re-bias the APD to a level where the power dissipated in the APD is significantly reduced enabling high levels of optical input power to be accommodated without catastrophic failure of the APD. The optical overload can be monitored during the protected state.

FIG. 7 shows for explanation purposes a simplified circuit diagram of an example of specific analogue protection circuitry for the detector of this second embodiment.

The APD is biased in a high voltage state VAPD through a current monitor circuit which provides current to a sense resistor RSense. The voltage produced across the sense resistor is divided by R1 and R2 to provide a signal to the negative input of the comparator. In normal operation, the signal is below the comparator set voltage defined by R3 and R4 and the output of the comparator is pulled high by the pull-up resistor. Under optical overload conditions, the signal voltage at the junction of R1 and R2 exceeds the comparator set voltage and the comparator output changes from a high to a low voltage, causing current to flow through D1 and the closed switch SW2 forcing the voltage at the comparator positive input to fall to approximately one diode drop above ground potential. The low output signal causes switch SW1 to change the bias to the APD to the protected bias condition, most usually a low voltage at which avalanche operation of the photo-detector does not occur, producing a lower photo current and reducing the power dissipated in the photo-detector, preventing device failure. Operation under these conditions allows continued monitoring of the photo-current to ensure removal of the overload condition before re-setting the APD bias. The ratio of R1 to R2 is chosen to ensure that the signal sent to the negative input of the comparator does not fall below the voltage on the positive input after the overload signal has been removed, forcing the comparator to latch in the protected state. The output of the comparator may be used to monitor the setting of the protected state. Opening of the switch SW2 removes the current through diode D1 allowing the comparator set voltage to be reset to the value defined by R3 and R4. If the overload is still present, the comparator output remains low and the APD remains under low bias conditions. If the optical overload has been removed the output of the comparator circuit is pulled high by the pull-up resistor and the switch SW1 resets to the high voltage bias for normal APD operation.

The APD bias under the protected state may be held at a value suitable for the particular device to be protected. Leaving the bias circuit open in the protect state may allow a greater degree of protection although the ability to monitor the photo-current under these conditions is removed.

Features of this second embodiment include: (1) Switching of APD bias voltage from M3-M10 level (high bandwidth, normally operating level) to low level (approx M1) allowing continuous monitoring of the overload; and (2) Circuit is latching and reset from external control.

FIG. 8 is a more detailed circuit diagram of a specific example of analogue protection circuitry for the detector of the second embodiment.

The output voltage is used to drive a comparator (MAX986EXK-T) circuit which has hysteresis such that when it is set, by a detection of a high enough current (say 110% of the maximum expected current), it remains turned on. In this condition it redirects the bias to the APD to be from the normal operating voltage (typically in the range of 19 to 26V) to a much lower value, at which the APD is operating in PIN mode. It has been observed that a voltage of 9V should ensure that the devices are always properly operating in the PIN mode. In such conditions, the current is reduced by at least a factor of 3, and more likely a factor of 10 from the normal operating condition. The photo-current is still monitored by the microprocessor. When the microprocessor determines that the current is less than the allowable operating maximum current, the APD is re-biased to a suitable level dependent on the input current. The turn on sequence could use both (i) a variable optical attenuator (VOA) upstream of the APD to attenuate the optical signal and (ii) appropriate bias conditions for the APD. The circuit is reset to use the higher APD operating bias by the application of a positive going pulse from the microprocessor. To avoid an unstable turn on/turn off sequence in the bias redirection circuit, the resetting is only allowed to exist for a transient time (˜6 us) by means of an RC high pass feed to the reset switch.

In FIG. 8, R8 may be omitted if the APD is to be open circuited in the event of excessive input power.

The APD is specified to 0 dBm. At this condition the gain will be set to M3. The input power is ImW and therefore the photo-current is 3 mA. This is the maximum specified current for the TIA. The power dissipated in the detector is 57 mW assuming a bias of 19 volts. This may be deemed to be the maximum safe level for the detector. Therefore, if the protection circuit is activated, the voltage is cut to 9V and the current is divided by approximately a factor of three, assuming the device operates in the PIN mode. Under these conditions the current is reduced to 1 mA and the power dissipation is reduced to 9 mW.

The protection circuit activates within the thermal time constant of the APD, which typically ranges from a few microseconds to a few tens of microseconds.

The input power required to produce 57 mW at M1 and 9 volts bias is 6.55 mW corresponding to about 8 dBm.

The protection afforded to the APD is not reliant on the VOA. Longer term protection with the VOA fully attenuating would constitute greater protection.

The microprocessor restores a safe power up procedure once it recognises that the unit has received a power overload. This could be done by looking for the loss of power alarm or loss of signal alarm. An alternative way is to simply sense an ADC level near to maximum, say greater than 1008. The signal required to achieve 2 mA (max sense voltage of 2V) is about −1.6 dBm at M3, so for greater input power levels the VOA is preferably in circuit.

The resolution of the ADC (1Obit) and the minimum safe setting of the low power level indicating low light level conditions will limit the ability of the microprocessor to recognise that the APD is detecting a real signal rather than just dark current leakage. A sensible minimum value would be 10 ADC points, corresponding to 2O mV sense voltage which is 2O uA current (for a Ik sense resistor). This puts the lower sense limit at −27 dBm.

FIG. 9 shows the response of the circuit to a sudden arrival of current, simulated by a positive transient from 0 to 2.5V, equivalent to an input current of 2.5 mA being detected.

Trace C shows the rising transient between 0 and 2.5V. Trace D shows the output to the APD falling from 23.6V to 9V. With this given level of overdrive, the delay is about 450 ns. This delay increases slightly with reduced overdrive, but with an overdrive level corresponding to 1OO uA (0.1V) the response time is still less than 600 ns. The response is not determined by the base level of the input signal. If the base level was at 1.9V (equivalent to 1.9 mA) then the increase to 2V would initiate the transition in a similar time.

FIG. 10 shows a full cycle in which the APD bias voltage as indicated by Trace E is initially in protected mode; low voltage, 9V. After the application of the reset pulse (see Trace F), the APD voltage increases to its normal operating regime. When an overload input occurs, the APD voltage immediately reduces to the protected mode. It is latched in this state and cannot be released until a reset pulse is sent (from the microprocessor). This is shown in FIG. 11. A reset pulse is continually sent (see Trace G) at regular intervals but only resets the APD Voltage (Trace H)) if the overload has been removed (see Trace J). A Schottky on the reset line is provided to clamp the negative going transition from the reset pulse trailing edge.

The reset line also monitors the output of the comparator circuit and detects when this is sent low as indicating an overload situation. An example of a sequence of events is:
1. During the power up sequence the reset pin is set to an output and a reset pulse is sent from the microprocessor to put the receiver into its normal operating mode (High APD voltage).
2. The reset pin on the microprocessor is set to an input.
3. The microprocessor determines that the hardware overload circuit has been tripped by monitoring the reset pin at regular intervals (for example, every 1 ms, 5 ms or 30 ms). The pin goes low indicating an overload.
4. After the reset pin is pulled low, the pin is set to output with a low on the pin.
5. The receiver is setup for overload conditions; e.g. M3 and VOA fully activated.
6. The current in the receive circuit is monitored to see if the overload prevails. If the current is acceptable, the comparator circuit is reset by sending a positive pulse to the reset pin.
7. The microprocessor is set back to input and test to repeat the monitoring process.

If the overload is still present, the reset pulse from the microprocessor will fail to reset the analogue protection circuit. Also, if required, the +9V supply could be isolated from the APD supply switch. This would enable the supply to be open circuited, possibly affording a higher level of protection. Under these conditions the microprocessor would not be able to determine the photocurrent and therefore will not recognise whether the overload still exists. However, it is still possible to bring the receiver back on line in a protected state by selecting M3 bias conditions and inserting maximum VOA attenuation. These could then be backed off until a useable signal is received. The APD gain and the VOA setting can then be used to verify if the overload is still present.

AC coupling of the reset pulse is used because during the reset pulse the hysteresis is disconnected. The overload signal detected would trip the protection circuit, cutting its gain. If this were to a level, because V=9 volts instead of 19V and M=I instead of 3-10, at which the overload condition was no longer satisfied, the unit would immediately return to the high gain state, whereupon the overload would again be sensed and the unit would trip itself again. This oscillation would proceed for the duration of the reset signal. By using a very short reset signal, the extent of this undefined state can be reduced.

The optical detectors described above have particular use in, for example, applications where a very high optical power may be applied to an APD receiver over a period of about less than 100 us (such as switching on a EDFA in a real system or an optical attenuator in a test lab).

The applicant draws attention to the fact that the present invention may include any feature or combination of features disclosed herein either implicitly or explicitly or any generalisation thereof, without limitation to the scope of any definitions set out above. In view of the foregoing description it will be evident to a person skilled in the art that various modifications may be made within the scope of the invention.

1-18. (canceled)

19. An optical detector including an avalanche photodiode (APD) and protection circuitry for protecting the APD from excessive power dissipation therewithin, wherein the protection circuitry includes a switching element connected in parallel with the APD, which switching element is switched from a high resistance state to a low resistance state if the level of current through the APD exceeds a predetermined level, and wherein switching back of the switching element to the high resistance state is dependent on a reset signal from a controller.

20. An optical detector according to claim 19, wherein the protection circuitry also includes a comparator whose output controls said switching element, wherein said comparator receives at its non-inverting input a voltage signal dependent on sum of the levels of current through the APD and the switching element and at its inverting input a reference voltage signal, and wherein the protection circuitry is configured such that switching of said switching element into the low resistance state has the effect of reducing the bias across the APD whilst not reducing the sum of the levels of current through the APD and the switching element, such that in the absence of said reset signal the switching element is latched in the low resistance state.

21. An optical detector according to claim 20, wherein the protection circuitry includes a resistor in series with both the APD and the switching element, the resistance value of the resistor being selected in relation to that of the APD and switching element such that switching the switching element into the low resistance state has the effect of reducing the bias voltage across the APD.

22. An optical detector according to claim 20, wherein the reset signal reduces the bias voltage across the APD and the switching element, whereby the sum of the levels of current through the APD and the switching element drops and said switching element is switched back into the high resistance state.

23. An optical detector according to claim 22, wherein after reducing said bias voltage the controller initiates ramping of said bias voltage back to a normal operation level.

24. An optical detector according to claim 20, wherein the output of the comparator is also connected to an input of the controller.

25. An optical detector including an avalanche photodiode (APD), and protection circuitry for protecting the APD from excessive power dissipation therewithin, wherein in the event that the level of current through the APD exceeds a predetermined level as a result of an optical overload, the protection circuitry switches the APD bias voltage to a relatively low bias voltage at which said optical overload can nonetheless still be detected, and wherein switching back of the APD bias voltage to a higher voltage state is dependent on a reset signal from a controller.

26. An optical detector including an avalanche photodiode (APD), and protection circuitry for protecting the APD from excessive power dissipation therewithin by switching the APD to a relatively low voltage power supply if the level of current through the APD exceeds a predetermined level, and wherein switching back of the APD to a higher voltage power supply is dependent on a reset signal from a controller.

27. An optical detector according to claim 26, wherein the protection circuitry includes a comparator which receives at its inverting input a voltage signal dependent on the level of current through the APD and at its non-inverting input a reference voltage signal, and wherein the protection circuitry is configured such that said reference voltage signal is automatically reduced when the APD is switched to the relatively low voltage power supply such that in the absence of said reset signal the APD is latched in a low bias voltage state even if the level of current through the APD falls back below said predetermined level.

28. An optical detector according to claim 27, wherein the protection circuitry includes a diode connected in series across the output and non-inverting input of the comparator.

29. An optical detector according to claim 28, wherein said diode is connected in series with a switch element across the output and non-inverting input of the comparator, said switch element being switchable between high and low resistance states, and wherein the controller resets the protection circuitry by activating said switch element so as to switch it first to said high-resistance state whereby the APD is switched back to a higher voltage power supply, and then switching it back to said low-resistance state.

30. An optical detector according to claim 29, wherein said low voltage power supply is one at which the controller can still determine the level of current through the APD.

31. An optical detector according to claim 30, wherein the controller receives via a current monitor, amplifier and analogue-digital convertor a digital input representative of the current through the APD, and upon determination that the current has dropped below a predetermined level indicating removal of optical overload sends said reset signal to switch the APD back to a higher voltage power supply.

32. An optical detector according to claim 26, wherein the controller also controls a variable optical attenuator (VOA) in the optical path to the APD.

33. An optical detector according to claim 32, wherein upon recognition of a switch of the APD to the low voltage power supply the controller sets the VOA to maximum attenuation

34. An optical detector according to claim 32, wherein upon recognition of a switch of the APD to said low voltage power supply, the controller sets the VOA for maximum attenuation and switches the APD to a higher voltage power supply.

35. An optical detector according to claim 25, further including a current monitor connected in series with the APD, and wherein the current monitor provides an output signal indicative of the APD current both under normal operation conditions and said overload condition.

36. Use of the optical detector according to claim 19 for measuring the power of an optical signal whilst protecting the APD from optical overload.
